(19) United States
(12) Patent Application Publication
(10) Pub. No.: US 2025/0040121 A1
(43) Pub. Date: Jan. 30, 2025

(54) MULTI-LAYER CAPACITORS FOR THREE-DIMENSIONAL MEMORY SYSTEMS

(71) Applicant: Micron Technology, Inc., Boise, ID (US)

(72) Inventors: Yuanzhi Ma, Boise, ID (US); Scott E. Sills, Boise, ID (US); Si-Woo Lee, Boise, ID (US); David K. Hwang, Boise, ID (US); Yoshitaka Nakamura, Boise, ID (US); Yuichi Yokoyama, Boise, ID (US); Pavani Vamsi Krishna Nittala, Boise, ID (US); Glen H. Walters, Baltimore, MD (US); Gautham Muthusamy, Boise, ID (US); Haitao Liu, Boise, ID (US); Kamal Karda, Boise, ID (US)

(21) Appl. No.: 18/777,208

(22) Filed: Jul. 18, 2024

Related U.S. Application Data
(60) Provisional application No. 63/528,860, filed on Jul. 25, 2023.

(51) Int. Cl. H10B 12/00; H10B 53/20; H10B 53/30

(52) U.S. Cl. CPC H10B 12/30; H10B 12/03; H10B 53/20; H10B 53/30

(57) ABSTRACT

Methods, systems, and devices for multi-layer capacitors for three-dimensional memory systems are described. Memory cells of a memory system may include capacitors having dielectric material between multiple interfaces (e.g., concentric interfaces) of a bottom electrode and a top electrode. A bottom electrode may include a first portion wrapping around a portion of a semiconductor material that is contiguous with a channel of a transistor, and a top electrode may include a first portion wrapping around the first portion of the bottom electrode. The bottom electrode may also include a second portion wrapping around the first portion of the top electrode, and the top electrode may also include a second portion wrapping around the second portion of the bottom electrode. The dielectric material may include respective portions between each interface of the bottom electrode and top electrode which, in some examples, may be a contiguous implementation of the dielectric material.

### CROSS REFERENCE

The present application for patent claims priority to U.S. Patent Application No. 63/528,860 by Ma et al., entitled “MULTI-LAYER CAPACITORS FOR THREE-DIMENSIONAL MEMORY SYSTEMS,” filed Jul. 25, 2023, which is assigned to the assignee hereof, and which is expressly incorporated by reference in its entirety herein.

### TECHNICAL FIELD

The following relates to one or more systems for memory, including multi-layer capacitors for three-dimensional memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory device that supports multi-layer capacitors for three-dimensional memory systems in accordance with examples as disclosed herein.

FIG. 2 shows an example of an array architecture that supports multi-layer capacitors for three-dimensional memory systems in accordance with examples as disclosed herein.

FIGS. 3 through 14B show examples of fabrication operations that support multi-layer capacitors for three-dimensional memory systems in accordance with examples as disclosed herein.

FIG. 15 shows a flowchart illustrating a method that supports multi-layer capacitors for three-dimensional memory systems in accordance with examples as disclosed herein.

### DETAILED DESCRIPTION

Some memory devices may include one or more three-dimensional arrays of memory cells formed over a substrate. For example, a memory device may include multiple levels of memory cells, where a level may refer to a dimension above the substrate (e.g., a level along one or more horizontal directions above a substrate). In some implementations, a memory cell may include a capacitor operable to store a charge indicative of logic state and a switching component (e.g., a cell selection component, a transistor) operable to couple the capacitor with an access line such that the logic state may be written to, or read from, or both from the capacitor, among other operations.

Reducing the physical size of memory cells may support increased array density, and thus an increased storage capacity of a memory device for a given size, among other benefits. However, reducing the physical size of memory cells may include reducing one or more dimensions of capacitors of the memory cells which, for some capacitor architectures, may reduce a capacity of the memory cells to store a charge that corresponds to a given logic state. The reduced capacity to store charge may be associated with relatively small read margins, relatively high refresh rates, or relatively complex access circuitry, among other accompanying characteristics.

In accordance with the examples described herein, a memory device may include memory cells having capacitors that support a capacitance with a relatively compact arrangement of material portions. For example, a capacitor of a memory cell may include multiple portions (e.g., layers) of dielectric material between portions, such as concentric portions, of a first electrode (e.g., a bottom plate) and a second electrode (e.g., a top plate). The first electrode may include a first portion that wraps around or is otherwise coupled with a portion of a semiconductor material that is contiguous with a channel of a transistor (e.g., a cell selection transistor), and the second electrode may include a first portion that wraps around the first portion of the first electrode (e.g., separated by a first portion of the dielectric material between the first portion of the first electrode and the first portion of the second electrode). The first electrode may also include a second portion that wraps around the first portion of the second electrode (e.g., separated by a second portion of the dielectric material between the first portion of the second electrode and the second portion of the first electrode), and the second electrode may include a second portion that wraps around the second portion of the first electrode (e.g., separated by a third portion of the dielectric material between the first portion of the first electrode and the first portion of the second electrode). Thus, the capacitor may include three interfaces (e.g., concentric interfaces, interfaces at different relative radial positions from an axis of the capacitor) between material portions of the first electrode and the second electrode, each across a respective portion of the dielectric material, which may support a relatively high capacitance in a relatively small volume. Such techniques may support a relatively dense array architecture, including for three-dimensional arrays of memory cells, which may support relatively high storage capacity, relatively low fabrication cost, or relatively low operational latency, among other benefits.

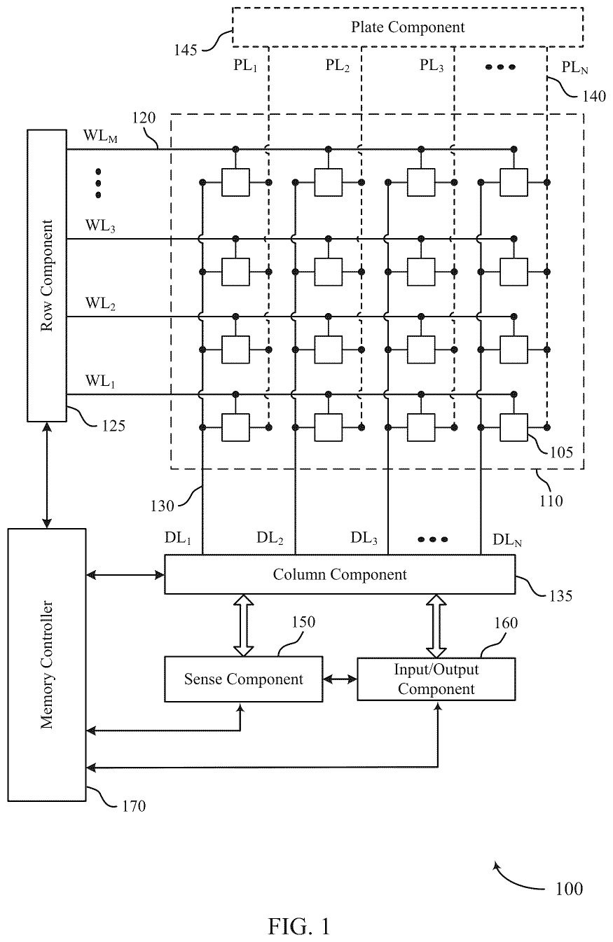

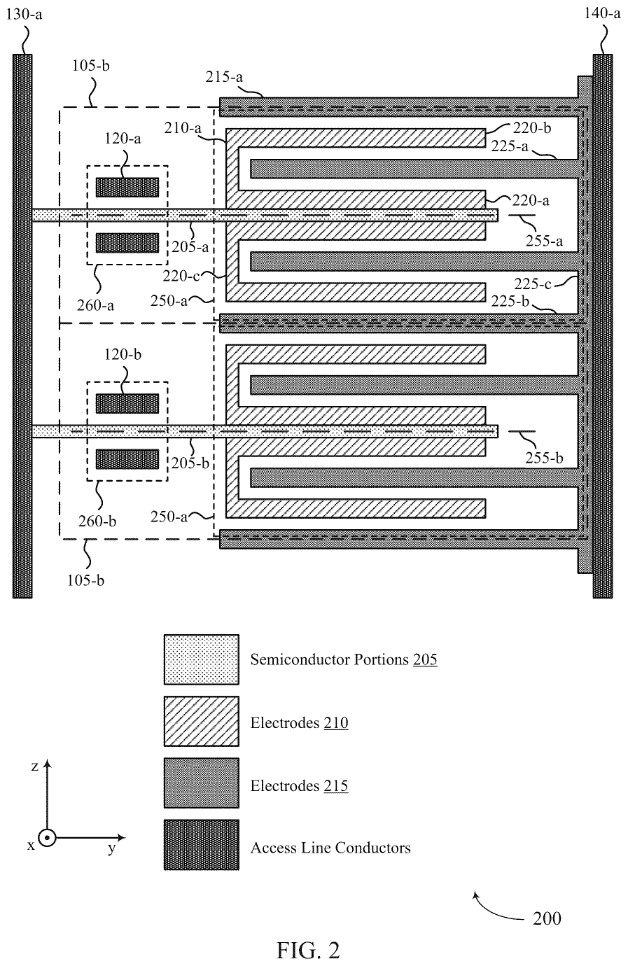

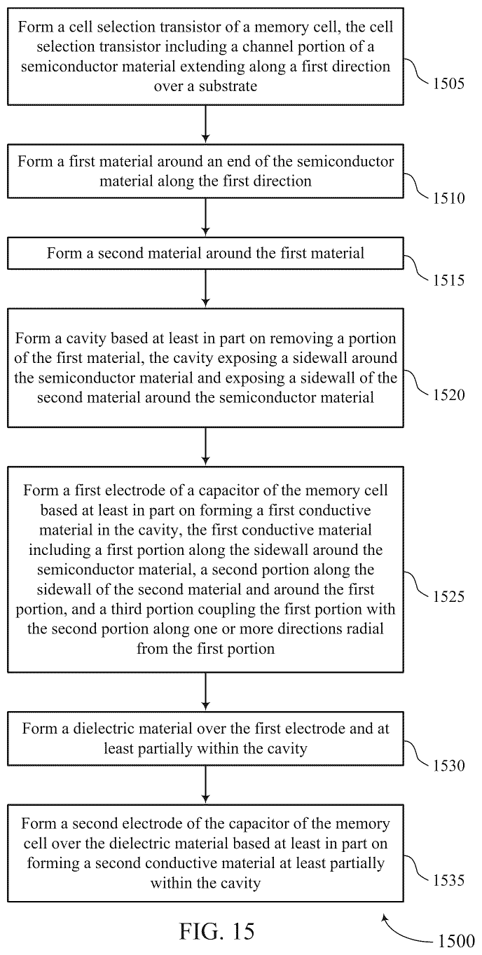

Features of the disclosure are initially described in the context of a memory device with reference to FIG. 1. Features of the disclosure are described in the context of an array architecture and fabrication operations as described with reference to FIGS. 2 through 14B. These and other features of the disclosure are described in the context of a flowchart that relates to multi-layer capacitors for three-dimensional memory systems with reference to FIG. 15.

FIG. 1 shows an example of a memory device 100 that supports multi-layer capacitors for three-dimensional memory systems in accordance with examples as disclosed herein. The memory device 100 may be referred to as a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100, where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component), and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 in the array 110). For implementations in which a memory cell 105 employs a capacitor for storing a logic state, a digit line 130 may provide access to a first terminal (e.g., a first plate) of the capacitor, and a plate line 140 may provide access to a second terminal (e.g., a second plate) of the capacitor. Although the plurality of plate lines 140 of the memory device 100 are shown as being parallel with the plurality of digit lines 130, in other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all of the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state written to or stored by the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

In some implementations, the memory device 100 may include one or more three-dimensional arrays of memory cells 105 formed over a substrate. For example, one or more arrays 110 may be formed above a substrate with word lines 120 arranged at different levels along a direction from a substrate and digit lines 130 arranged at different positions along a direction above a substrate (e.g., with each digit line 130 extending along the direction from the substrate and each word line 120 extending along the direction above the substrate). Additionally, or alternatively, one or more arrays 110 may be formed above a substrate with digit lines 130 arranged at different levels along a direction from a substrate and word lines 120 arranged at different positions along a direction above a substrate. Reducing the physical size of memory cells 105 may support increased density of such arrays 110, and thus an increased storage capacity for a given size of the arrays 110, among other benefits. However, reducing the physical size of memory cells 105 may include reducing one or more dimensions of capacitors of the memory cells which, for some capacitor architectures, may reduce a capacity of the memory cells 105 to store a charge that corresponds to a given logic state. The reduced capacity to store charge may be associated with relatively small read margins, relatively high refresh rates, or relatively complex access circuitry, among other accompanying characteristics of the memory device 100.

In accordance with the examples described herein, a memory device 100 may include memory cells 105 having capacitors that support a capacitance with a relatively compact arrangement of material portions. For example, a capacitor of a memory cell 105 may include multiple portions (e.g., layers) of dielectric material between portions, such as concentric portions of a first electrode (e.g., a bottom plate) and a second electrode (e.g., a top plate). The first electrode may include a first portion that wraps around or is otherwise coupled with a portion of a semiconductor material that is contiguous with a channel of a transistor (e.g., a cell selection transistor), and the second electrode may include a first portion that wraps around the first portion of the first electrode (e.g., separated by a first portion of the dielectric material between the first portion of the first electrode and the first portion of the second electrode). The first electrode may also include a second portion that wraps around the first portion of the second electrode (e.g., separated by a second portion of the dielectric material between the first portion of the second electrode and the second portion of the first electrode), and the second electrode may include a second portion that wraps around the second portion of the first electrode (e.g., separated by a third portion of the dielectric material between the first portion of the first electrode and the first portion of the second electrode). Thus, the capacitor may include three interfaces (e.g., concentric interfaces, interfaces at different relative positions relative to an axis or center portion of the capacitor) between material portions of the first electrode and the second electrode, each across a respective portion of the dielectric material, which may support a relatively high capacitance in a relatively small volume. Such techniques may support a relatively dense architecture for arrays 110, including for three-dimensional arrays of memory cells 105, which may support relatively high storage capacity, relatively low fabrication cost, or relatively low operational latency of the memory device 100, among other benefits.

In addition to applicability in memory systems as described herein, techniques for manufacturing multi-layer capacitors for three-dimensional memory systems may be generally implemented to improve the performance (including gaming) of various electronic devices and systems. Some electronic device applications, including gaming and other high-performance applications, may be associated with relatively high processing characteristics while also benefitting from relatively quick response times to improve user experience. As such, increasing processing speed, decreasing response times, or otherwise improving the performance electronic devices may be desirable. Implementing the techniques described herein may improve the performance of electronic devices by increasing the capacitance of three-dimensional arrays of volatile memory cells (e.g., DRAM cells, FeRAM cells), which may improve memory access speeds, decrease processing times, decrease latency times, improve response times, or otherwise improve user experience, among other benefits.

FIG. 2 shows an example of an array architecture 200 that supports multi-layer capacitors for three-dimensional memory systems in accordance with examples as disclosed herein. The array architecture 200 may illustrate an example for implementing aspects of an array 110 in a memory device 100, which may include features formed above a substrate (not shown), such as features formed above a crystalline semiconductor wafer. For example, the array architecture 200 may illustrate an architecture of memory cells 105, which may be implemented in a three-dimensional array 110. Aspects of the array architecture 200 may be described with reference to an x-direction, a y-direction, and a z-direction, with the example of FIG. 2 providing an illustrative cross-sectional view of features of the array architecture 200 in a yz-plane. In some implementations, the x-direction may be a direction over (e.g., parallel to, above) the substrate, the y-direction may be another direction over (e.g., parallel to, above) the substrate, and the z-direction may be a direction away from the substrate (e.g., perpendicular to or otherwise away from a surface of the substrate, a height direction, a thickness direction). In some other implementations, the x-direction may be a direction away from a substrate, the y-direction may be a direction over the substrate, and the z-direction may be another direction over the substrate. Aspects of the array architecture 200 may be repeated in various quantities and arrangements along the x-direction, the y-direction, and the z-direction to support various three-dimensional configurations of memory cells 105.

In the example of array architecture 200, each memory cell 105 includes a respective capacitor 250 and a respective transistor 260 (e.g., a cell selection transistor). Each memory cell 105 (e.g., of a column of memory cells 105 along the z-direction) may also be associated with a digit line 130 (e.g., digit line 130-a associated with memory cells 105-a and 105-b, extending along the z-direction) and a respective word line 120 (e.g., word line 120-a associated with memory cell 105-a, word line 120-b associated with memory cell 105-b, each extending along the x-direction). The word lines 120 may act as a gate of or be otherwise coupled with a gate of the transistors 260, and biasing a word line 120 (e.g., with an activation bias, with a selection bias) may be operable to couple the capacitor 250 of a memory cell 105 with a digit line 130 (e.g., based on activating a channel of the respective transistor 260). The array architecture 200 also includes a plate line 140-a coupled with the capacitors 250 and extending along at least the z-direction. In some examples, the plate line 140-a may be associated with a column of memory cells 105 that include the memory cells 105-a and 105-b. In some examples, the plate line 140-a may also extend along the x-direction, which may include being coupled with additional memory cells 105 along the x-direction (e.g., as a common plate for multiple columns of memory cells 105 arranged along the x-direction.

Each of the memory cells 105 may be associated with a respective semiconductor portion 205 that extends along the y-direction (e.g., from the digit line 130-a). At least a portion of the semiconductor portion 205 associated with a memory cell 105 may support a channel of the transistor 260 associated with the memory cell 105. For example, the word line 120-a, operating as a gate of the transistor 260-a, may be operable to modulate a conductivity of a channel portion of the semiconductor portion 205-a. In some examples, word lines 120 may be associated with one or more conductors that extend along the x-direction adjacent to the semiconductor portions 205 (e.g., in a pass-by gate configuration). In some examples, the word lines 120 may be associated with conductor portions that wrap around the semiconductor portions 205 (e.g., in an all-around gate configuration, where semiconductor portions 205 extend through openings in word lines 120).

The semiconductor portions 205 may include various semiconductor materials, such as silicon (e.g., crystalline silicon, epitaxial silicon, polysilicon), and portions of the semiconductor portions 205 associated with the transistors 260 may be doped to support the channel characteristics of the transistors 260. For example, to support an n-type transistor configuration for the transistors 260, the semiconductor portions 205 may include n-type doping, or a portion with p-type doping between portions with n-type doping (e.g., along the y-direction), among other doping configurations. The semiconductor portions 205 may be formed with various cross-sectional shapes (e.g., in an xz-plane), such as with a circular cross-section, an oval cross-section, a square cross-section, a rectangular cross-section, a polygonal cross-section, and others. In some examples, the semiconductor portions 205 may referred to as a stud of a capacitor 250 or of a memory cell 105.

Each capacitor 250 may be associated with an electrode 210 (e.g., a bottom electrode) coupled with a transistor 260, an electrode 215 (e.g., a top electrode) coupled with the plate line 140-a, and a dielectric material (not shown) between the electrode 210 and the electrode 215. For example, the capacitor 250-a may be associated with an electrode 210-a and an electrode 215-a, and so on. In various examples, the electrodes 215 may be formed with a same material (e.g., a contiguous material) as the plate line 140-a, or may be formed with a different material than the plate line 140-a, or may be otherwise electrically coupled with the plate line 140-a. In some examples, at least a portion of (e.g., an outer portion of) an electrode 215 may be shared between capacitors 250 of adjacent memory cells 105 in an array 110, which may provide a shielding effect between electrodes 210 of adjacent memory cells 105, which may reduce disturbance effects between the adjacent memory cells 105. In some examples, at least a portion of electrodes 210 may be formed in contact with (e.g., around an end of, in contact with an end of) respective semiconductor portions 205, or may be otherwise coupled with a channel of a respective transistor 260. The electrodes 210 and electrodes 215 may be formed from various materials such as titanium nitride or other conductive materials, and electrodes 215 may be formed with a same material as electrodes 210 or with a different material than electrodes 210.

The electrodes 210 and electrodes 215 may include various material portions that are formed around (e.g., in a concentric manner) a respective axis 255 (e.g., axes along the y-direction, an axis through a respective semiconductor portion 205-a, an axis along a direction of a channel of a transistor 260), where such portions may be formed around an end of a respective semiconductor portion 205 (e.g., an end along the y-direction). For example, the electrode 210-a may include a portion 220-a, which may be in contact with and wrap around the semiconductor portion 205-a, and a portion 220-b, which may wrap around the portion 220-a. In some examples, the portion 220-a and the portion 220-b may be formed with a contiguous material, which may include a portion 220-c that extends at least in part along one or more radial directions (e.g., directions radial to the axis 255-a) between the portion 220-a and the portion 220-b. Accordingly, the electrode 210 may be configured in a toroidal shape (e.g., a cupped shape) having a cavity (e.g., a depression, a well) on an end of the electrode 210 between the portion 220-a and the portion 220-b, as illustrated in FIG. 2. Although the semiconductor portion 205-a is illustrated as extending through the portion 220-a, in some other examples, the portion 220-a may be contiguous over (e.g., may cover) the end of the semiconductor portion 205-a.

The electrode 215-a may include a portion 225-a and a portion 225-b. The portion 225-a may be arranged between the portion 220-a and the portion 220-b, and may wrap around the portion 220-a. In some examples, the portion 225-a may be contiguous over (e.g., may cover) an end of the portion 220-a, an end of the portion of the semiconductor portion 205-a, or both. The portion 225-b may wrap around the portion 220-b, such that the portion 220-b is positioned between the portion 225-a and the portion 225-b. In some examples, the portion 225-a and the portion 225-b may be formed with a contiguous material, which may include a portion 225-c that extends at least in part along one or more radial directions (e.g., directions radial to the axis 255-a) between the portion 225-a and the portion 225-b. In some cases, the portion 225-b may have a greater extent (e.g., along the negative y-direction) than the portion 225-a. For example, the portion 225-b may extend to or beyond an end of the electrode 210, as illustrated in FIG. 2. Such an extension may enhance an ability of the portion 225-b to act as a barrier (e.g., a shield) between adjacent memory cells 105 (e.g., between adjacent electrodes 210), which may mitigate disturbance effects between adjacent memory cells 105 (e.g., disturbances associated with access operations on one or both of adjacent memory cells 105).

A dielectric material between the electrode 210 and the electrode 215 may support a capacitance between the electrode 210 and the electrode 215, with which a charge indicative of a logic state may be stored in a memory cell 105. In some examples, such a dielectric material may include one or more materials that support a linear capacitance (e.g., for operating memory cells 105 in accordance with a DRAM architecture). In some examples, such a dielectric material may include one or more materials that support a ferroelectric capacitance (e.g., a polarization, for operating memory cells 105 in accordance with an FeRAM architecture).

A dielectric material may contiguously extend between portions 220 of the electrode 210 and portions 225 of the electrode 215. For example, for the capacitor 250-a, a dielectric material may include a first portion arranged between the portion 220-a and the portion 225-a that wraps around the portion 220-a, a second portion arranged between the portion 225-a and the portion 220-b that wraps around the portion 225-a, and a third portion arranged between the portion 220-b and the portion 225-b that wraps around the portion 220-b. In some cases, the dielectric material may be contiguous between the portions (e.g., with one or more portions that extend along one or more directions radial to the axis 255-a). For example, the first portion of the dielectric material may be contiguous with the second portion over an end of portion 225-a, and the second portion may be contiguous with the third portion over an end of the portions 220-b. In such cases, the portion 220-a may be contiguous with the portion 220-b over an end of the first portion and the second portion, and the portion 225-a may be contiguous with the portion 225-b over an end of the second portion, an end of the portion 220-b, and an end of the third portion. Because the dielectric material may be implemented with three concentric interfaces between an electrode 210 and an electrode 215 for each capacitor 250 (e.g., interfaces at different positions or layers radially from a respective axis 255), the capacitors 250 may be referred to as three-sided stud capacitors, which may provide a relatively large capacitance in a relatively small volume.

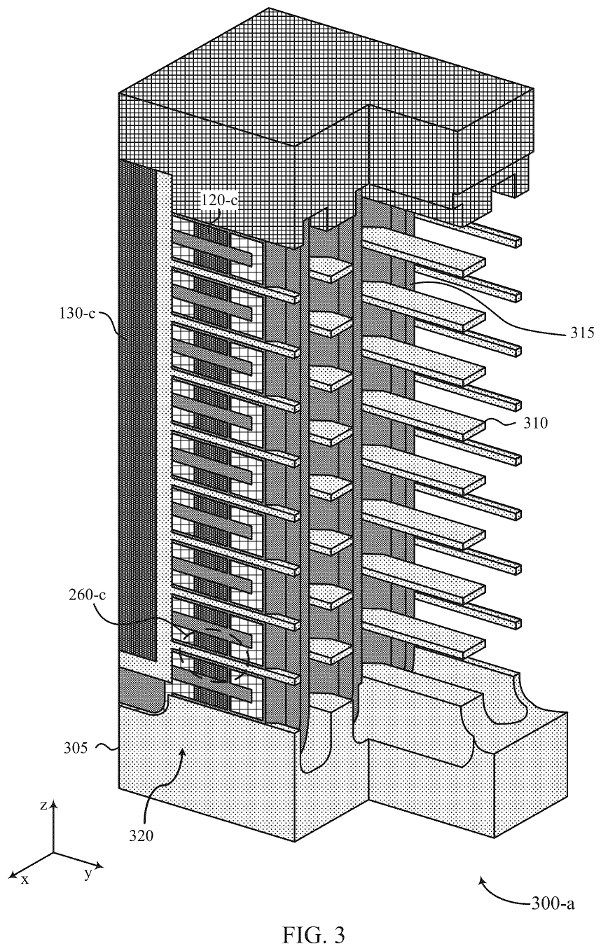

FIGS. 3 through 13 illustrate examples of fabrication operations that support multi-layer capacitors for three-dimensional memory systems in accordance with examples as disclosed herein. For example, FIGS. 3 through 13 may illustrate operations for fabricating aspects of a material arrangement 300, which may be a portion of a memory device (e.g., a portion of a memory device 100), and may include aspects of the array architecture 200. Each of FIGS. 3 through 13 may illustrate aspects of the material arrangement 300 after different subsets of the fabrication operations for forming the material arrangement 300 (e.g., illustrated as a material arrangement 300-a after a first set of one or more fabrication operations, as a material arrangement 300-b after a second set of one or more fabrication operations, and so on). Each view of FIGS. 3 through 13 may be described with reference to an x-direction, a y-direction, and a z-direction, as illustrated, which may correspond to the respective directions described with reference to the array architecture 200. Aspects of the material arrangement 300 may be illustrated in accordance with cut planes (e.g., along xz-planes, along yz-planes) to show various embedded features of the material arrangement 300.

Operations illustrated in and described with reference to FIGS. 3 through 13 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the material arrangement 300. In some examples, operations performed by such a manufacturing system may be supported by a process controller or its components as described herein.

Although aspects of the material arrangement 300 illustrate examples of relative dimensions and quantities of various features, aspects of the material arrangement 300 may be implemented with other relative dimensions or quantities of such features in accordance with examples as disclosed herein. Moreover, aspects of the material arrangement 300 may be repeated in various manners (e.g., along the x-direction, along the y-direction, along the z-direction) to support a three-dimensional architecture of memory cells 105. In the following description of the material arrangement 300, some methods, techniques, processes, and operations may be performed in different orders, or at different times, or otherwise modified. Further, some operations for fabricating a material arrangement 300 (e.g., for fabrication in accordance with an array architecture 200) may be omitted from the described fabrication operations, or other operations may be added to the described fabrication operations.

FIG. 3 illustrates the material arrangement 300 (e.g., as a material arrangement 300-a) after a first set of one or more fabrication operations. The first set of operations may include forming an access region 320 of a memory device. For example, the first set of operations may include forming one or more digit lines 130-c extending along the z-direction (e.g., away from a substrate 305), one or more word lines 120-c extending along the x-direction (e.g., over the substrate 305), and a material 315, such as an oxide material, which may provide an electrical isolation between features of the access region 320.

Forming the access region 320 may also include forming transistors 260-c, which may include channels formed from portions of semiconductor material portions 310. The semiconductor material portions 310 may be arranged in a two-dimensional array along the x-direction and the z-direction (e.g., an array in an xz-plane). Each semiconductor material portion 310 may extend along the y-direction (e.g., over the substrate 305), and may include a channel region of a respective transistor 260-c through, between, or adjacent to corresponding word lines 120-c (e.g., operating as a gate of the respective transistor 260-a). The semiconductor material portions 310 may extend away from the access region along the y-direction, and may be associated with exposed studs of the semiconductor material (e.g., unsupported studs).

In some examples, forming the semiconductor material portions 310 may implement epitaxial formation techniques (e.g., epitaxial deposition). For example, the substrate 305 may have a crystalline atomic arrangement, and the crystalline arrangement of the substrate 305 may be translated through (e.g., contiguous through) alternating portions (e.g., layers, levels) of the semiconductor material (e.g., of the semiconductor material portions 310) and another material (e.g., a sacrificial material). To support such techniques, the semiconductor material and the other material may be selected to support translation of the crystalline arrangement from the substrate 305 as the portions are formed (e.g., deposited) along the z-direction (e.g., across boundaries between and through the semiconductor material and the other material). In some examples, the substrate 305 may be the same semiconductor material as the semiconductor material portions 310 (e.g., silicon or other semiconductor), and the other material may be a compound of the semiconductor material or another material that is otherwise compatible for translating the atomic arrangement of the substrate 305. For example, the semiconductor material may be silicon (e.g., epitaxial silicon) and the other material may be silicon germanium (e.g., epitaxial silicon germanium). In some examples, the semiconductor material and the other material may also be selected to support differential processing techniques, such as selecting the other material to support being preferentially removed while maintaining portions of the semiconductor material for forming the semiconductor material portions 310. In some examples, the other material may be removed (e.g., exhumed) and replaced with the material 315, or another material, or various combinations thereof. Some other examples may implement other techniques for forming the semiconductor material portions 310 with a crystalline atomic arrangement or a polycrystalline atomic arrangement.

In some cases, the first set of operations may include doping the semiconductor material portions 310. For example, for transistors 260-c having an n-type configuration, the first set of operations may include doping ends of the semiconductor material portions 310, including exposed studs, with an n-type doping material (e.g., using a gas phase doping operation, using diffusion doping from a sacrificial material, or a combination thereof). Doping the ends of the semiconductor material portion 310 may form a concentration of an n-type dopant (e.g., a concentration greater than 1e18 per cubic centimeter (cm), a concentration greater than 1e20 per cubic cm, a concentration greater than 1e21 per cubic cm). In some examples, the first set of operations may also include doping portions of the semiconductor material portions (e.g., in the channel regions of the transistors 260-c, between n-type doped portions) with a p-type doping material (e.g., to provide an npn transistor junction).

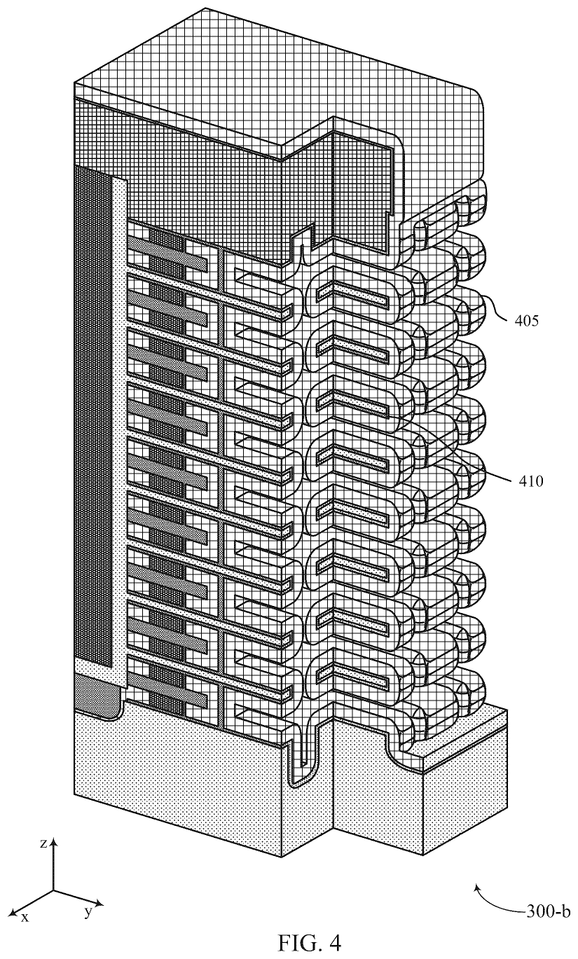

FIG. 4 illustrates the material arrangement 300 (e.g., as a material arrangement 300-b) after a second set of one or more fabrication operations. The second set of operations may include operations that support forming a material 405 (e.g., an insulating material, such as a nitride) around ends of the semiconductor material portions 310. For example, the second set of operations may include depositing the material 405 on exposed portions of the access region (e.g., the exposed portions of the material 315) and on the exposed portions of the semiconductor material portions 310.

In some examples, the second set of operations may also include forming a material 410 (e.g., a liner material, such as an oxide material) on at least the semiconductor material portions 310 (e.g., prior to forming the material 405). For example, the second set of operations may include depositing the material 410 and subsequently depositing the material 405. In some cases, the material 410 may be the same material as the material 315 (e.g., may be the same oxide material).

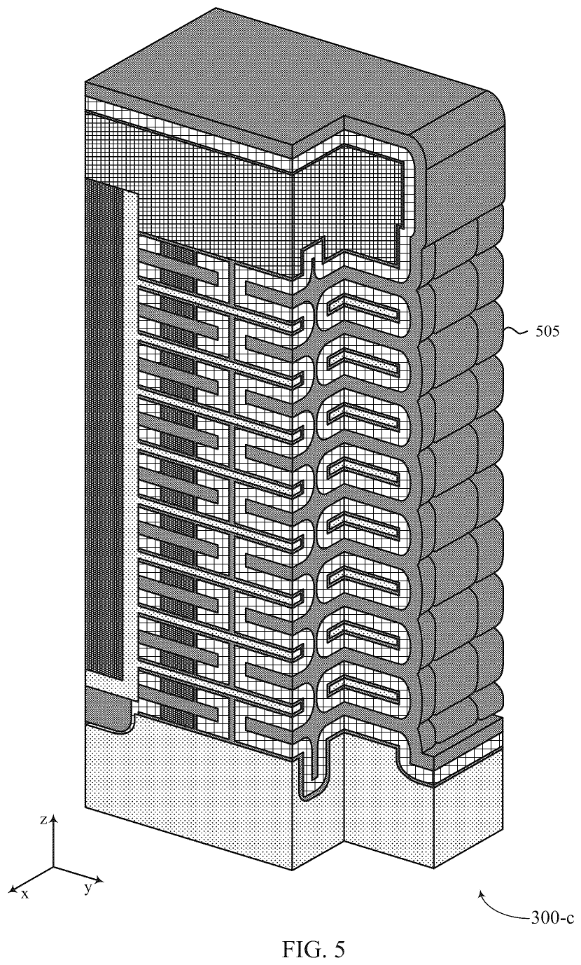

FIG. 5 illustrates the material arrangement 300 (e.g., as a material arrangement 300-c) after a third set of one or more fabrication operations. The third set of operations may include operations that support forming a material 505 (e.g., an insulating material, such as an oxide) over (e.g., around) the material 405. For example, the third set of operations may include depositing the material 505 on sidewalls of the material 405. In some cases, depositing the material 505 may fill spaces between adjacent semiconductor material portions 310 and deposited material 405, as illustrated in FIG. 5. In some cases, the material 505 may be the same material as the material 315, the material 410, or both (e.g., may be the same oxide material).

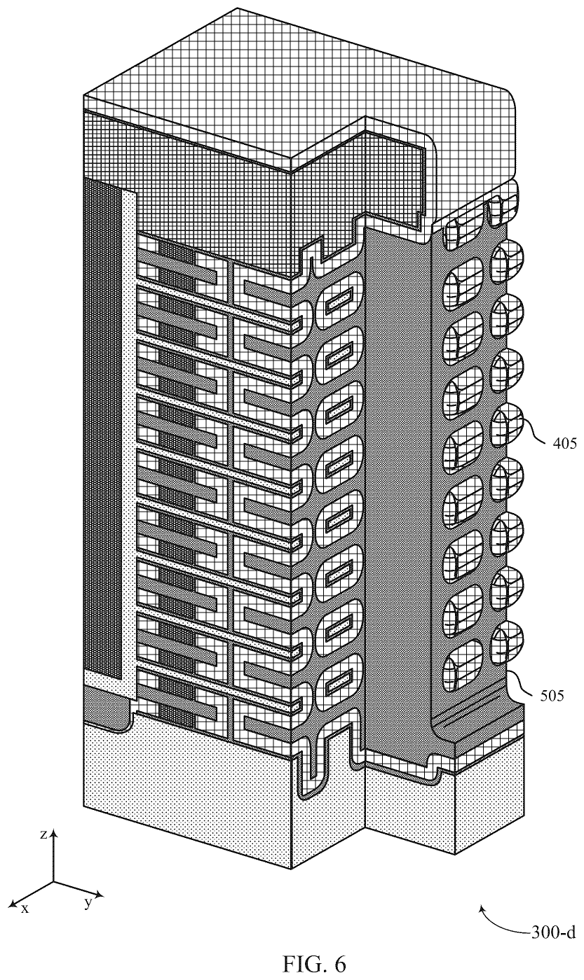

FIG. 6 illustrates the material arrangement 300 (e.g., as a material arrangement 300-d) after a fourth set of one or more fabrication operations. The fourth set of operations may include operations that support removing portions of the material 505. For example, the fourth set of operations may include a recess operation configured to remove a portion of the material 505 while leaving other material, such as the material 405, and some other portions of the material 505, intact. Accordingly, removing the portions of the material 505 may expose at least a first portion of the material 405, while leaving a second portion of the material 405 covered by the remaining material 505.

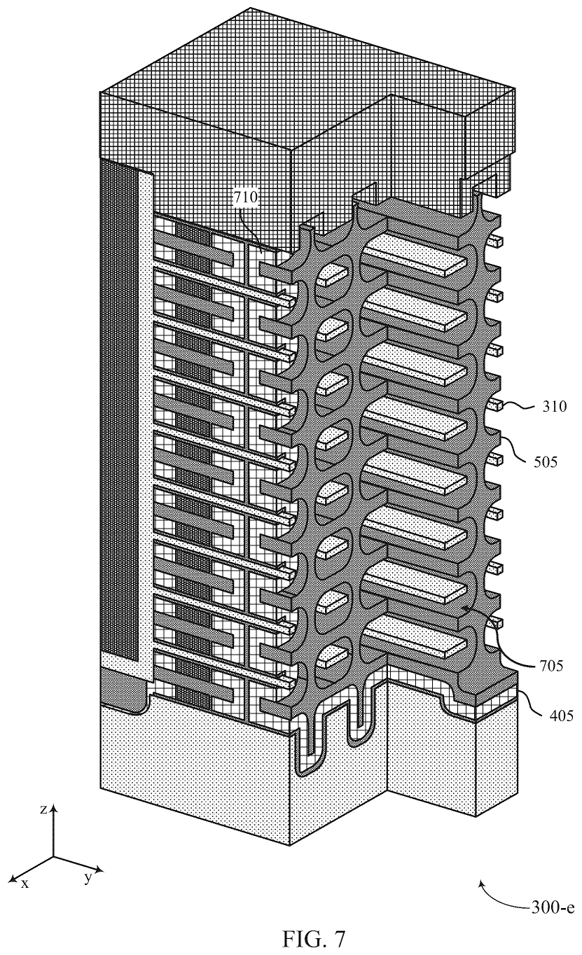

FIG. 7 illustrates the material arrangement 300 (e.g., as a material arrangement 300-c) after a fifth set of one or more fabrication operations. The fifth set of operations may include operations that support removing portions of the material 405 to form cavities 705. For example, the fourth set of operations may include a recess operation configured to remove at least a portion of the material 405 while leaving other material, such as the material 505, the semiconductor material portions 310, or both intact. Accordingly, removing the portions of the material 405 may expose sidewalls around the semiconductor material portions 310, and may expose sidewalls of the material 505 around the semiconductor material portions 310. In some cases, where applicable, the fifth set of operations may include removing at least a portion of the material 410, which may expose the ends of semiconductor material portions 310.

In some examples, removing the portions of the material 405 may form one or more structures 710 from the remaining portions of the material 405. A structure 710 may include a cavity (e.g., a depression, a well) in which another material, such as the material 505, may be arranged. In some examples, structures 710 may provide mechanical support for subsequent features of the material arrangement 300. In some examples, a presence of structures 710 may be indicative that aspects of the operations described herein have been performed to form the material arrangement 300.

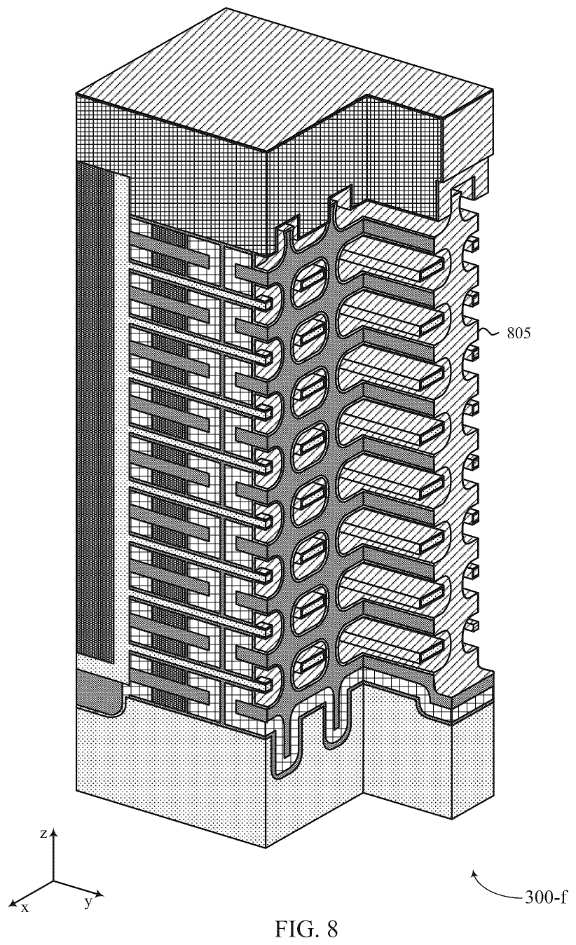

FIG. 8 illustrates the material arrangement 300 (e.g., as a material arrangement 300-f) after a sixth set of one or more fabrication operations. The sixth set of operations may include operations that support forming a material 805 (e.g., a conductive material, such as titanium nitride) on exposed portions of the material arrangement 300. For example, the sixth set of operations may include depositing the material 805 within each of the cavities 705 to cover exposed sidewalls of the material 505 within the cavities 705, as well as depositing the material 805 to cover the semiconductor material portions 310 within the cavities 705.

The material 805 within each cavity 705 may form the electrode 210 as described with reference to FIG. 2. For example, the material 805 deposited on the semiconductor material portions 310 may form the portion 220-a of the electrode 210, and the material 805 deposited on the sidewalls of the material 505 within the cavities 705 may form the portion 220-b of the electrode 210.

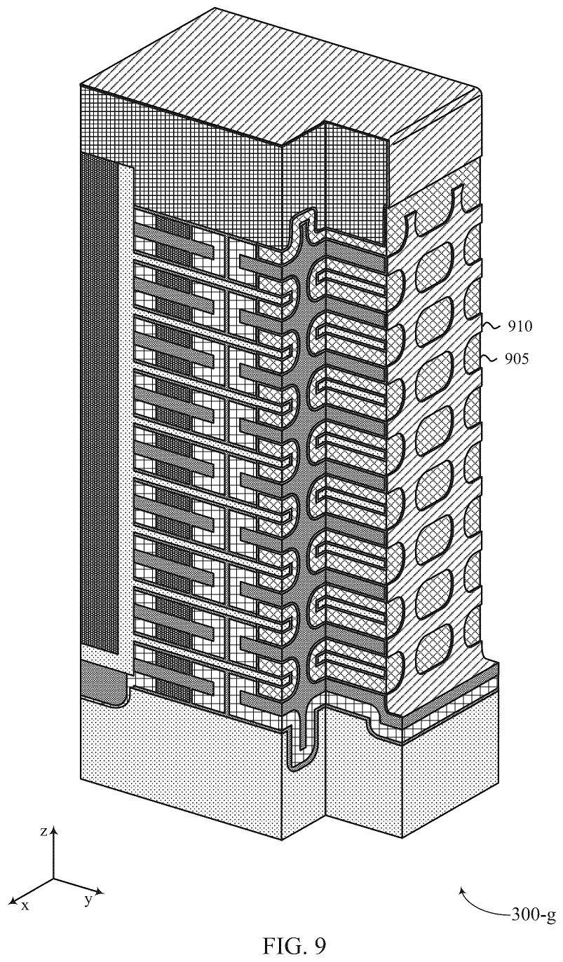

FIG. 9 illustrates the material arrangement 300 (e.g., as a material arrangement 300-g) after a seventh set of one or more fabrication operations. The seventh set of operations may include operations that support forming a material 905 (e.g., a placeholder material, a sacrificial material) to fill the cavities 705. For example, the seventh set of operations may include depositing the material 905 to cover exposed portions of the material arrangement 300, which may fill the cavities 705 with the material 905, or cover an outer sidewall 910 of the material 805 (e.g., a sidewall exterior to the cavities 705), or both. In some cases, the seventh set of operations may include removing a portion of the material 905, for example using a recess operation, to recess the material 905 into the cavities 705 and to expose the outer sidewall 910 of the material 805.

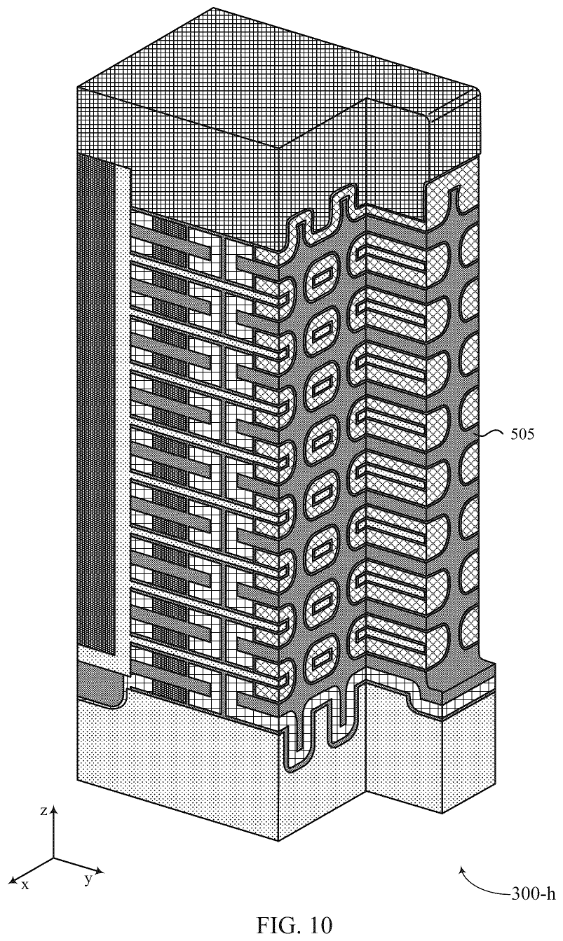

FIG. 10 illustrates the material arrangement 300 (e.g., as a material arrangement 300-h) after a eighth set of one or more fabrication operations. The eighth set of operations may include operations that support removing the outer sidewall 910 of the material 805 to separate the material 805 within each cavity 705 from the material 805 within a different cavity 705 (e.g., to separate electrodes 210 of adjacent capacitors 250). For example, the eighth set of operations may include a recess operation to remove the outer sidewall 910 of the material 805 to expose the material 505.

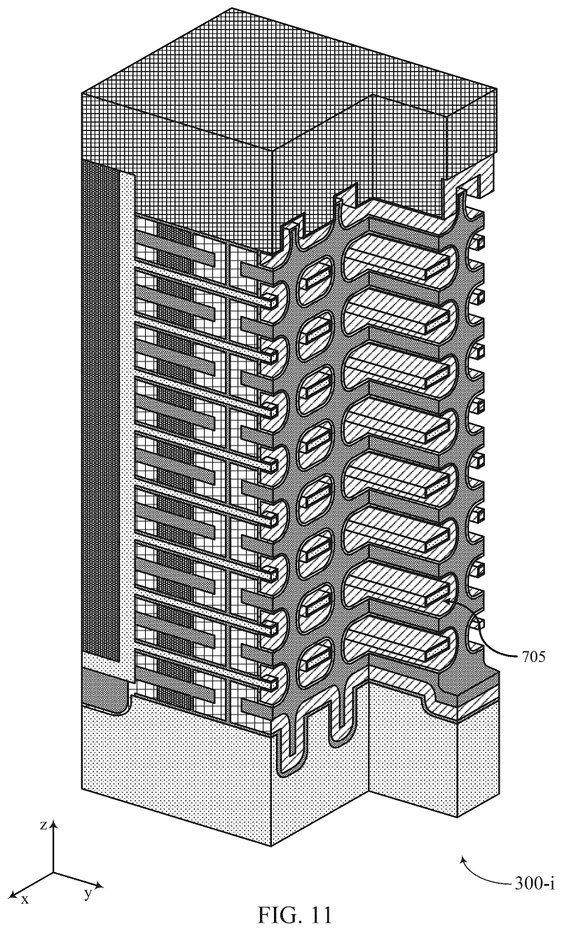

FIG. 11 illustrates the material arrangement 300 (e.g., as a material arrangement 300-i) after a ninth set of one or more fabrication operations. The ninth set of operations may include operations that support removing the remaining portions of the material 905 to expose the material 805 within each cavity 705. For example, the ninth set of operations may include an etching procedure to remove the material 905, which may expose the material 805 (e.g., corresponding to portions 220-a and portions 220-b of electrodes 210).

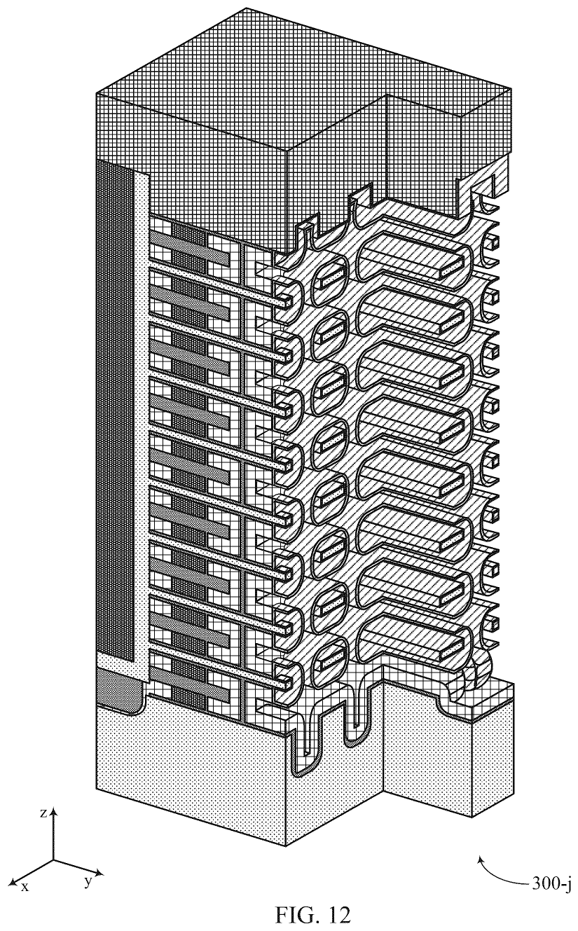

FIG. 12 illustrates the material arrangement 300 (e.g., as a material arrangement 300-j) after a tenth set of one or more fabrication operations. The tenth set of operations may include operations that support removing the remaining portions of the material 505 to expose portions of the material 805 (e.g., to expose electrodes 210). For example, the tenth set of operations may include a material removal procedure, such as a stop on film process, to remove remaining exposed portions of the material 505. In some examples, removing the material 505 may expose sidewalls of the material 805 (e.g., outer sidewalls of the portions 220-b).

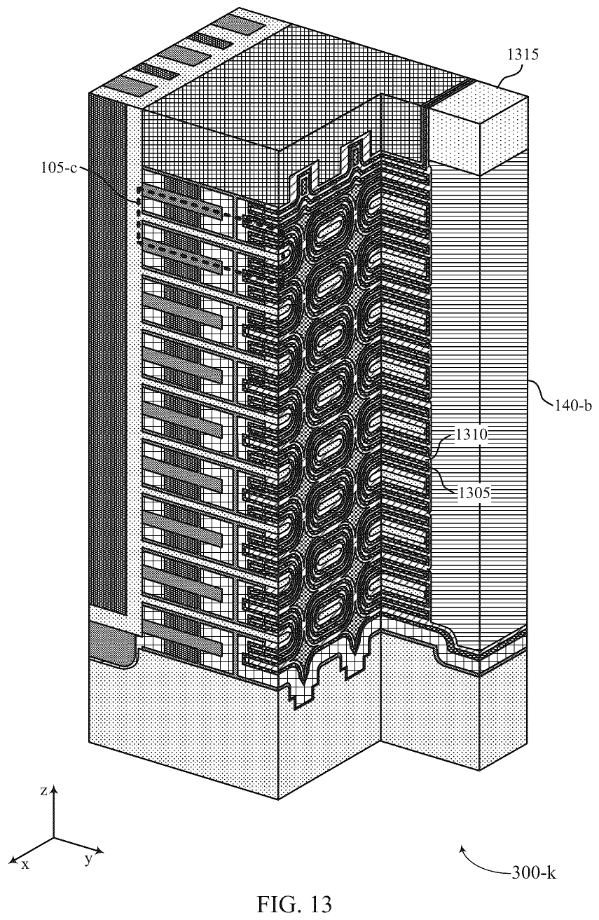

FIG. 13 illustrates the material arrangement 300 (e.g., as a material arrangement 300-k) after an eleventh set of one or more fabrication operations. The eleventh set of operations may include operations that support forming electrodes 215 and dielectric material between the electrodes 215 and the electrodes 210. For example, the eleventh set of operations may include depositing a material 1305 on the exposed portions of the material 805 (e.g., on the exposed portions of the electrode 210). Additionally, the eleventh set of operations may include depositing a material 1310 on the material 1305.

The material 1305 may be an example of a dielectric material, which may have a relatively high dielectric constant (e.g., a relative to other insulating materials of the material arrangement 300, such as the material 405, the material 505, or both), and may accordingly be referred to as a high-k material. In some examples, the material 1305 may have ferroelectric properties, which may support operation in accordance with a ferroelectric capacitance. The material 1310 may be an example of a conductive material such as titanium nitride, and may act as an electrode for memory cells 105-c (e.g., electrodes 215). Accordingly, the eleventh set of operations may form capacitors 250 of the memory cells 105-c, for which the material 805 may support first plates (e.g., electrodes 210) of the capacitors 250, the material 1310 may support second plates (e.g., electrodes 215) of the capacitor 250, and the material 1305 may support a dielectric film between the first plates and the second plates.

In some cases, the eleventh set of operations may include forming a plate line 140-b (e.g., a conductive plate) extending along the z-direction, and a contact 1315 arranged above (e.g., in the z-direction, on top of the plate line 140-b). For example, eleventh set of operations may include depositing a conductive material to contact the material 1310, which may form the plate line 140-b, and depositing a second conducive material to form the contact 1315. In some cases, the conductive material of the plate line 140-b may be different than the conductive material of the electrode 210, the electrode 215, or both. For example, the conductive material of the plate line 140-b may include boron, silicon, germanium, or a combination thereof, such as a boron silicon germanium alloy.

Because the material 1305 may have a relatively high dielectric property, the material 1305 may provide a similarly high capacitance for the capacitor of the memory cells 105-c. Additionally, the layered arrangement (e.g., three concentric layers) of the material 1305 may support a relatively high surface area of the material 1305 for the capacitors 250 (e.g., relative to an arrangement having fewer layers), which may support relatively high capacitance in a relatively small volume.

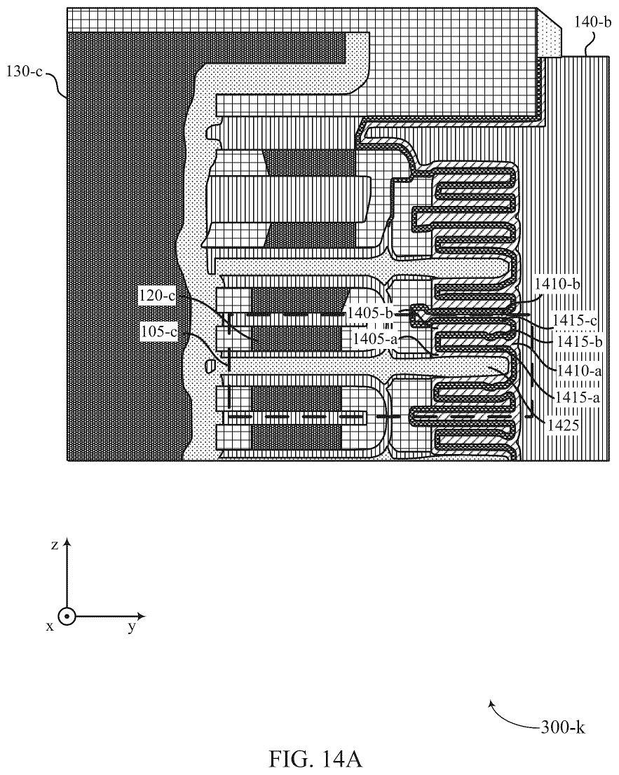

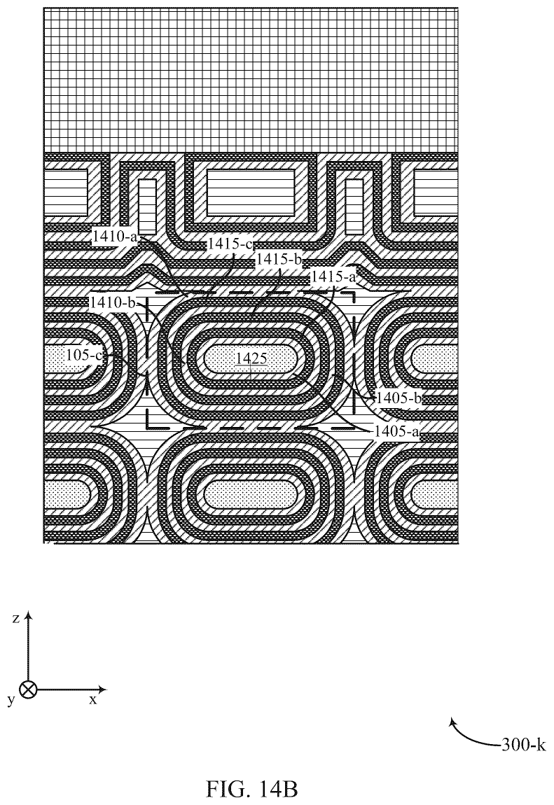

FIGS. 14A and 14B shows an example of the material arrangement 300 (e.g., as the material arrangement 300-k) in a cross-sectional view in a yz-plane and in a cross-sectional view in an xz-plane, respectively. For example, FIGS. 14A and 14B may illustrate aspects of a three-dimensional array of memory cells 105-c with word lines 120-c extending along the x-direction, digit lines 130-c extending along the z-direction, and plate line 140-b extending along the x-direction and along the z-direction.

The memory cells 105-c may each include a capacitor 250 having an electrode 1405 (e.g., a bottom electrode), an electrode 1410 (e.g., a top electrode) coupled with the plate line 140-b, and a dielectric material 1415 between the electrode 1405 and the electrode 1410. The electrode 1405 may extend around a central axis extending along the y-direction and through the portion of the semiconductor material 1425.

Each electrode 1405 may include one or more portions 220, such as a portion 1405-a, which may be in contact with the portion of the semiconductor material 1425 and may wrap around (e.g., be concentric with) the central axis (e.g., around the semiconductor material 1425), and a portion 1405-b which may wrap around the portion 1405-a and may be contiguous with the portion 1405-a. As shown, the portion 1405-a may wrap around an end of the semiconductor material 1425. Alternatively, the portion 1405-a may form a lumen with an open end around the semiconductor material 1425.

The electrode 1410 may include a second conductive material, which may be a same material as the electrode 1405, or may be a different conductive material. The electrode 1410 may wrap around the central axis, and may include one or more portions 225, such as a portion 1410-a and a portion 1410-b. The portion 1410-a may be arranged between the portion 1405-a and the portion 1405-b, and may wrap around the portion 1405-a. Additionally, the portion 1410-b may wrap around the portion 1405-b. In some cases, the portion 1410-b may have a greater length (e.g., in the y-direction) than the portion 1410-a. For example, the portion 1410-b may extend to or beyond an end of the electrode 1405. Such an extension may allow the portion 1410-b to act as a barrier (e.g., a shield) between adjacent memory cells 105-c, which may mitigate disturb effects between adjacent memory cells 105-c. In some examples, the portion 1410-a may be contiguous over an end of the portion 1405-a and over an end of the portion of the semiconductor material 1425.

The dielectric material 1415 may contiguously extend between portions of the electrode 1405 and portions of the electrode 1410. For example, the dielectric material 1415 may include a portion 1415-a arranged between the portion 1405-a and the portion 1410-a which wraps around the portion 1405-a, a portion 1415-b arranged between the portion 1410-a and the portion 1405-b which wraps around the portion 1410-a, and a portion 1415-c arranged between the portion 1405-b and the portion 1410-b which wraps around the portion 1405-b.

In some cases, the dielectric material 1415 may be contiguous between the portions thereof. For example, the portion 1415-a may be contiguous with the portion 1415-b over an end of portion 1410-a, and the portion 1415-b may be contiguous with the portion 1415-c over an end of the portions 1410-b. In such cases, the portion 1405-a may be contiguous with the portion 1405-b over an end of the first portion and the second portion, and the portion 225-a may be contiguous with the portion 1410-b over an end of the portion 1415-b, an end of the portion 1405-b, and an end of the portion 1415-c.

FIG. 15 shows a flowchart illustrating a method 1500 that supports multi-layer capacitors for three-dimensional memory systems in accordance with examples as disclosed herein. The operations of method 1500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1505, the method may include forming a cell selection transistor (e.g., a transistor 260) of a memory cell, the cell selection transistor including a channel portion of a semiconductor material (e.g., a semiconductor material portion 310) extending along a first direction (e.g., a y-direction) over a substrate (e.g., a substrate 305).

At 1510, the method may include forming a first material (e.g., a material 405) around an end (e.g., about the x-direction) of the semiconductor material along the first direction.

At 1515, the method may include forming a second material (e.g., a material 505) around the first material.

At 1520, the method may include forming a cavity (e.g., a cavity 705) based at least in part on removing a portion of the first material, the cavity exposing a sidewall around the semiconductor material and exposing a sidewall of the second material around the semiconductor material.

At 1525, the method may include forming a first electrode (e.g., an electrode 210) of a capacitor of the memory cell based at least in part on forming a first conductive material (e.g., a material 805) in the cavity, the first conductive material including a first portion (e.g., a portion 220-a) along the sidewall around the semiconductor material, a second portion (e.g., a portion 220-b) along the sidewall of the second material and around the first portion, and a third portion (e.g., a portion 220-c) coupling the first portion with the second portion along one or more directions radial from (e.g., radially from the x-direction) the first portion.

At 1530, the method may include forming a dielectric material (e.g., a material 1305) over the first electrode and at least partially within the cavity.

At 1535, the method may include forming a second electrode (e.g., an electrode 215) of the capacitor of the memory cell over the dielectric material based at least in part on forming a second conductive material (e.g., a material 1310) at least partially within the cavity.

In some examples, an apparatus (e.g., a manufacturing system) as described herein may perform a method or methods, such as the method 1500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a cell selection transistor of a memory cell, the cell selection transistor including a channel portion of a semiconductor material extending along a first direction over a substrate; forming a first material around an end of the semiconductor material along the first direction; forming a second material around the first material; forming a cavity based at least in part on removing a portion of the first material, the cavity exposing a sidewall around the semiconductor material and exposing a sidewall of the second material around the semiconductor material; forming a first electrode of a capacitor of the memory cell based at least in part on forming a first conductive material in the cavity, the first conductive material including a first portion along the sidewall around the semiconductor material, a second portion along the sidewall of the second material and around the first portion, and a third portion coupling the first portion with the second portion along one or more directions radial from the first portion; forming a dielectric material over the first electrode and at least partially within the cavity; and forming a second electrode of the capacitor of the memory cell over the dielectric material based at least in part on forming a second conductive material at least partially within the cavity.
Aspect 2: The method or apparatus of aspect 1, where the second conductive material includes a fourth portion between the first portion of the first conductive material and the second portion of the first conductive material, a fifth portion around the second portion of the first conductive material, and a sixth portion coupling the fourth portion with the fifth portion along one or more directions radial from the fourth portion.
Aspect 3: The method or apparatus of any of aspects 1 through 2, where the first conductive material is formed over the end (e.g., along the x-direction) of the semiconductor material.
Aspect 4: The method or apparatus of any of aspects 1 through 3, where forming the cavity exposes a portion of the first material at an end of the cavity (e.g., along the x-direction) that extends between semiconductor material and the sidewall of the second material.
Aspect 5: The method or apparatus of any of aspects 1 through 4, further including operations, features, circuitry, logic, means, or instructions, or any combination thereof for forming a third material in the cavity after forming the first conductive material; removing a portion of the first conductive material external to the cavity after forming the third material; and removing the third material from the cavity after removing the portion of the first conductive material external to the cavity, where forming the dielectric material is performed after removing the third material.
Aspect 6: The method or apparatus of any of aspects 1 through 5, further including operations, features, circuitry, logic, means, or instructions, or any combination thereof for removing the second material, where forming the dielectric material is performed after removing the second material.
Aspect 7: The method or apparatus of any of aspects 1 through 6, further including operations, features, circuitry, logic, means, or instructions, or any combination thereof for forming a conductive plate extending along a second direction away from the substrate and along a third direction over the substrate, the conductive plate in contact with a portion of the second conductive material.
Aspect 8: The method or apparatus of any of aspects 1 through 7, where the first material includes a nitride material and the second material includes an oxide material.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:
Aspect 9: An apparatus, including: a cell selection transistor of a memory cell (e.g., a memory cell 105), the cell selection transistor including a channel extending along a first direction (e.g., a y-direction) over a substrate (e.g., a substrate 305); and a capacitor of the memory cell coupled with the channel of the cell selection transistor and associated with an axis along the first direction over the substrate, the capacitor including: a first portion of a first electrode of the capacitor aligned along the axis; a first portion of a dielectric of the capacitor around the first portion of the first electrode about the axis; a first portion of a second electrode of the capacitor around the first portion of the dielectric about the axis; a second portion of the dielectric around the first portion of the second electrode about the axis; a second portion of the first electrode around the second portion of the dielectric about the axis; a third portion of the dielectric around the second portion of the first electrode about the axis; and a second portion of the second electrode around the third portion of the dielectric about the axis.
Aspect 10: The apparatus of aspect 9, further including: a semiconductor material portion, a first portion of the semiconductor material portion including the channel of the cell selection transistor, and the first portion of the first electrode around a second portion of the semiconductor material portion about the axis.
Aspect 11: The apparatus of aspect 10, where the first portion of the first electrode is in contact with the second portion of the semiconductor material portion.
Aspect 12: The apparatus of any of aspects 10 through 11, where the first portion of the first electrode is contiguous over an end of the second portion of the semiconductor material portion.
Aspect 13: The apparatus of any of aspects 9 through 12, where the first portion of the dielectric is contiguous with the second portion of the dielectric over an end of the first portion of the second electrode along the first direction.
Aspect 14: The apparatus of any of aspects 9 through 13, where the second portion of the dielectric is contiguous with the third portion of the dielectric over an end of the second portion of the first electrode along the first direction.
Aspect 15: The apparatus of any of aspects 9 through 14, where the first portion of the first electrode is contiguous with the second portion of the first electrode over an end of the first portion of the dielectric along the first direction and over an end of the second portion of the dielectric along the first direction.
Aspect 16: The apparatus of aspect 15, where the first portion of the second electrode is contiguous over an end of the first portion of the dielectric along the first direction and contiguous over an end of the first portion of the first electrode along the first direction.
Aspect 17: The apparatus of any of aspects 9 through 16, where the first portion of the second electrode is contiguous with the second portion of the second electrode over an end of the second portion of the dielectric and over an end of the third portion of the dielectric.
Aspect 18: The apparatus of any of aspects 9 through 17, where the cell selection transistor further includes a gate including a first access line extending along a second direction over the substrate, and the cell selection transistor is coupled with a second access line extending along a third direction away from the substrate.
Aspect 19: The apparatus of any of aspects 9 through 18, where the cell selection transistor further includes a gate including a first access line extending along a second direction away from the substrate, and the cell selection transistor is coupled with a second access line extending along a third direction over the substrate.
Aspect 20: The apparatus of any of aspects 9 through 19, further including: a conductive plate in contact with the second electrode and extending along a second direction away from the substrate and a third direction over the substrate.

An apparatus is described. The following provides an overview of aspects of the apparatus as described herein:
Aspect 21: An apparatus formed by a process including: forming a cell selection transistor of a memory cell, the cell selection transistor including a channel portion of a semiconductor material extending along a first direction over a substrate; forming a first material around an end of the semiconductor material along the first direction; forming a second material around the first material; forming a cavity based at least in part on removing a portion of the first material, the cavity exposing a sidewall around the semiconductor material and exposing a sidewall of the second material around the semiconductor material; forming a first electrode of a capacitor of the memory cell based at least in part on forming a first conductive material in the cavity, the first conductive material including a first portion along the sidewall around the semiconductor material, a second portion along the sidewall of the second material and around the first portion, and a third portion coupling the first portion with the second portion along one or more directions radial from the first portion; forming a dielectric material over the first electrode and at least partially within the cavity; and forming a second electrode of the capacitor of the memory cell over the dielectric material based at least in part on forming a second conductive material at least partially within the cavity.
Aspect 22: The apparatus of aspect 21, where the second conductive material includes a fourth portion between the first portion of the first conductive material and the second portion of the first conductive material, a fifth portion around the second portion of the first conductive material, and a sixth portion coupling the fourth portion with the fifth portion along one or more directions radial from the fourth portion.
Aspect 23: The apparatus of any of aspects 21 through 22, where the first conductive material is formed over the end of the semiconductor material.
Aspect 24: The apparatus of aspect 23, formed by the process further including: removing the second material, where forming the dielectric material is performed after removing the second material.
Aspect 25: The apparatus of any of aspects 21 through 24, formed by the process further including: forming a conductive plate extending along a second direction away from the substrate and along a third direction over the substrate, the conductive plate in contact with a portion of the second conductive material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, or firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a cell selection transistor of a memory cell, the cell selection transistor comprising a channel extending along a first direction over a substrate; and
a capacitor of the memory cell coupled with the channel of the cell selection transistor and associated with an axis along the first direction over the substrate, the capacitor comprising:
a first portion of a first electrode of the capacitor aligned along the axis;
a first portion of a dielectric of the capacitor around the first portion of the first electrode about the axis;
a first portion of a second electrode of the capacitor around the first portion of the dielectric about the axis;
a second portion of the dielectric around the first portion of the second electrode about the axis;
a second portion of the first electrode around the second portion of the dielectric about the axis;
a third portion of the dielectric around the second portion of the first electrode about the axis; and
a second portion of the second electrode around the third portion of the dielectric about the axis.

2. The apparatus of claim 1, further comprising:
a semiconductor material portion, a first portion of the semiconductor material portion comprising the channel of the cell selection transistor, and the first portion of the first electrode around a second portion of the semiconductor material portion about the axis.

3. The apparatus of claim 2, wherein the first portion of the first electrode is in contact with the second portion of the semiconductor material portion.

4. The apparatus of claim 2, wherein the first portion of the first electrode is contiguous over an end of the second portion of the semiconductor material portion.

5. The apparatus of claim 1, wherein the first portion of the dielectric is contiguous with the second portion of the dielectric over an end of the first portion of the second electrode along the first direction.

6. The apparatus of claim 1, wherein the second portion of the dielectric is contiguous with the third portion of the dielectric over an end of the second portion of the first electrode along the first direction.

7. The apparatus of claim 1, wherein the first portion of the first electrode is contiguous with the second portion of the first electrode over an end of the first portion of the dielectric along the first direction and over an end of the second portion of the dielectric along the first direction.

8. The apparatus of claim 7, wherein the first portion of the second electrode is contiguous over an end of the first portion of the dielectric along the first direction and contiguous over an end of the first portion of the first electrode along the first direction.

9. The apparatus of claim 1, wherein the first portion of the second electrode is contiguous with the second portion of the second electrode over an end of the second portion of the dielectric and over an end of the third portion of the dielectric.

10. The apparatus of claim 1, wherein the cell selection transistor further comprises a gate comprising a first access line extending along a second direction over the substrate, and the cell selection transistor is coupled with a second access line extending along a third direction away from the substrate.

11. The apparatus of claim 1, wherein the cell selection transistor further comprises a gate comprising a first access line extending along a second direction away from the substrate, and the cell selection transistor is coupled with a second access line extending along a third direction over the substrate.

12. The apparatus of claim 1, further comprising:
a conductive plate in contact with the second electrode and extending along a second direction away from the substrate and a third direction over the substrate.

13. A method, comprising:
forming a cell selection transistor of a memory cell, the cell selection transistor comprising a channel portion of a semiconductor material extending along a first direction over a substrate;
forming a first material around an end of the semiconductor material along the first direction;
forming a second material around the first material;
forming a cavity based at least in part on removing a portion of the first material, the cavity exposing a sidewall around the semiconductor material and exposing a sidewall of the second material around the semiconductor material;
forming a first electrode of a capacitor of the memory cell based at least in part on forming a first conductive material in the cavity, the first conductive material comprising a first portion along the sidewall around the semiconductor material, a second portion along the sidewall of the second material and around the first portion, and a third portion coupling the first portion with the second portion along one or more directions radial from the first portion;
forming a dielectric material over the first electrode and at least partially within the cavity; and
forming a second electrode of the capacitor of the memory cell over the dielectric material based at least in part on forming a second conductive material at least partially within the cavity.

14. The method of claim 13, wherein the second conductive material comprises a fourth portion between the first portion of the first conductive material and the second portion of the first conductive material, a fifth portion around the second portion of the first conductive material, and a sixth portion coupling the fourth portion with the fifth portion along one or more directions radial from the fourth portion.

15. The method of claim 13, wherein the first conductive material is formed over the end of the semiconductor material.

16. The method of claim 13, wherein forming the cavity exposes a portion of the first material at an end of the cavity that extends between semiconductor material and the sidewall of the second material.

17. The method of claim 13, further comprising:
forming a third material in the cavity after forming the first conductive material;
removing a portion of the first conductive material external to the cavity after forming the third material; and
removing the third material from the cavity after removing the portion of the first conductive material external to the cavity, wherein forming the dielectric material is performed after removing the third material.

18. The method of claim 13, further comprising:
removing the second material, wherein forming the dielectric material is performed after removing the second material.

19. The method of claim 13, further comprising:
forming a conductive plate extending along a second direction away from the substrate and along a third direction over the substrate, the conductive plate in contact with a portion of the second conductive material.

20. An apparatus formed by a process comprising:
forming a cell selection transistor of a memory cell, the cell selection transistor comprising a channel portion of a semiconductor material extending along a first direction over a substrate;
forming a first material around an end of the semiconductor material along the first direction;
forming a second material around the first material;
forming a cavity based at least in part on removing a portion of the first material, the cavity exposing a sidewall around the semiconductor material and exposing a sidewall of the second material around the semiconductor material;
forming a first electrode of a capacitor of the memory cell based at least in part on forming a first conductive material in the cavity, the first conductive material comprising a first portion along the sidewall around the semiconductor material, a second portion along the sidewall of the second material and around the first portion, and a third portion coupling the first portion with the second portion along one or more directions radial from the first portion;
forming a dielectric material over the first electrode and at least partially within the cavity; and
forming a second electrode of the capacitor of the memory cell over the dielectric material based at least in part on forming a second conductive material at least partially within the cavity.
